(19) United States
(12) Patent Application Publication
(10) Pub. No.: US 2025/0067928 A1
(43) Pub. Date: Feb. 27, 2025

(54) SELF-ALIGNED THREE-DIMENSIONAL OPTICAL PHASED ARRAY AND FABRICATION THEREOF

(71) Applicant: The Regents of the University of Michigan, Ann Arbor, MI (US)

(72) Inventors: Dachuan WU, Dearborn, MI (US); Yasha YI, Troy, MI (US)

(21) Appl. No.: 18/811,011

(22) Filed: Aug. 21, 2024

Related U.S. Application Data
(60) Provisional application No. 63/533,775, filed on Aug. 21, 2023.

(51) Int. Cl. G02B 6/12; C23C 16/02; C23C 16/24; C23C 16/40; G02B 6/293

(52) U.S. Cl. CPC G02B 6/12007; C23C 16/0245; C23C 16/24; C23C 16/402; G02B 6/29301

(57) ABSTRACT

An optical phased array, device incorporating the same, and method for fabricating the same. The method, describable as a method for fabricating a three-dimensional (3D) optical phased array (OPA), includes: simultaneously etching multiple waveguide-cladding layers to form a plurality of waveguide paths, each of which terminates at a common edge; and/or generating a waveguide-cladding stack having a plurality of waveguide layers and a plurality of cladding layers, and simultaneously etching multiple layers of a waveguide-cladding stack to form a plurality of waveguide paths, each of which terminates at a common edge. The optical phased array has a plurality of self-aligned waveguide layers.

### GOVERNMENT FUNDING

This invention was made with government support under 1428069 awarded by the National Science Foundation. The government has certain rights in the invention.

### TECHNICAL FIELD

This disclosure relates to optical phased arrays and devices incorporating optical phased array(s), such as those used for light detection and ranging (LIDAR or lidar), and methods for manufacturing optical phased arrays, namely three-dimensional (3D) end-firing or edge-firing optical phased arrays.

### BACKGROUND

Optical phased arrays (OPAs) are used in various devices to guide light (including, for example, infrared and/or near-infrared electromagnetic radiation), such as for use in lidar applications, and may be coupled to a light source and/or a light sensor so that waveguides or waveguide paths within the optical phased array guide light appropriately between a collector side (at which the light source/light sensor are located) to an emitter side (at which emitters (emitting or firing portions) are located). At the emitter side, light passes between the optical phased array and the atmosphere (or another medium). It will be appreciated that the term “light” is used herein in the context of optical phased arrays and that non-visible light may be transmitted and/or received by the OPA device—for example, in the context of LiDAR, a broader spectrum than just visible light is commonly used, such as electromagnetic radiation having infrared and ultraviolet wavelengths.

An edge-firing two-dimensional (2D) emitter is fabricated through generating a pattern layer and a cladding layer (collectively, the pattern layer and cladding layer are referred to as a waveguide layer) on a base substrate. An edge-firing three-dimensional (3D) OPA may be manufactured by stacking multiple waveguide layers on top of one another.

### SUMMARY

According to a first aspect of the invention, there is provided a method of fabricating a three-dimensional (3D) optical phased array (OPA). The method includes simultaneously etching multiple waveguide-cladding layers to form a plurality of waveguide paths, each of which terminates at a common edge.

According to other aspects of the invention, the method of the first aspect further includes any of the following features, including any technically-feasible combination of the following features:
the simultaneous etching is carried out using dry etching;
the simultaneous etching is carried out using reactive ion etching (RIE);
a mask layer is applied to a top side of a waveguide-cladding stack having the plurality of waveguide-cladding layers prior to the simultaneous etching step;
the mask layer and the waveguide-cladding stack are simultaneously etched;
the mask layer is etched prior to the simultaneous etching of the multiple layers of the waveguide-cladding stack;
two or more of the plurality of waveguide paths include an omega-shaped path portion;
the method includes obtaining a waveguide-cladding stack having the plurality of waveguide-cladding layers, wherein the waveguide-cladding stack is fabricated using a chemical vapor deposition (CVD) process so as to generate layers of the waveguide-cladding stack that are evenly distributed on a deposition surface thereby resulting in an even thickness of the layers; and/or
the 3D OPA is an edge-firing OPA.

According to a second aspect of the invention, there is provided a 3D edge-firing OPA fabricated according to the method of the first aspect.

According to a third aspect of the invention, there is provided an OPA device having the 3D edge-firing OPA of the second aspect.

According to a fourth aspect, there is provided a method of fabricating a three-dimensional (3D) edge-firing optical phased array (OPA). The method includes generating a waveguide-cladding stack having a plurality of waveguide layers and a plurality of cladding layers; and simultaneously etching multiple layers of a waveguide-cladding stack to form a plurality of waveguide paths, each of which terminates at a common edge.

According to other aspects of the invention, the method of the fourth aspect further includes any of the following features, including any technically-feasible combination of the following features:
the plurality of waveguide layers and the plurality of cladding layers are interposed so that the waveguide-cladding stack is comprised of alternating waveguide and cladding layers;
disposing a mask layer on a top side of the waveguide-cladding stack, and wherein the simultaneous etching step is performed by etching the waveguide-cladding stack while the mask layer is on the top side of the waveguide-cladding stack; and/or
the mask layer is etched according to a waveguide pattern prior to performing the simultaneous etching step, and wherein the simultaneous etching step is performed according to the waveguide pattern.

According to a fifth aspect of the invention, there is provided an optical phased array having a plurality of self-aligned waveguide layers.

According to other aspects of the invention, the optical phased array of the fifth aspect further includes any of the following features, including any technically-feasible combination of the following features:
the plurality of self-aligned waveguide layers is four or more self-aligned waveguide layers;
the plurality of self-aligned waveguide layers is six or more self-aligned waveguide layers;
the plurality of self-aligned waveguide layers is eight or more self-aligned waveguide layers; and/or
a total number of waveguide layers of the optical phased array is between six and eight, inclusive.

### BRIEF DESCRIPTION OF THE DRAWINGS

Preferred exemplary embodiments will hereinafter be described in conjunction with the appended drawings, wherein like designations denote like elements, and wherein:

FIG. 1 is a block diagram depicting an embodiment of a three-dimensional (3D) OPA device having an OPA with an on-chip edge coupler, according to at least one embodiment;

FIG. 2 is a block diagram depicting an embodiment of the OPA includes a Silicon-based structure, which may be a Silicon-on-insulator (SOI) platform having a plurality of Silicon-based two-dimensional (2D) waveguide arrays, according to at least one embodiment;

FIG. 3 is a side view of an exemplary 3D OPA having four waveguide layers that may be used as the OPA of the OPA device of FIG. 1, according to at least one embodiment;

FIG. 4 is a plan view, block diagram of the OPA of FIG. 2 with an expanded portion of the tree splitter or multimode interferometer (MMI), according to at least one embodiment;

FIG. 5 is a plan view, block diagram of the OPA of FIG. 4 with an expanded portion of a phase delay modulator or phase shifter portion is shown in which the waveguide paths each follow an omega-shaped delay path, according to at least one embodiment;

FIG. 6 is a schematic isometric view of an embodiment of an eight-layer 3D edge-firing OPA, showing a single mode fiber (SMF) coupling light into the device and a 2D 8×16 emitter array formed at the edge of the device, according to at least one embodiment;

FIG. 7 is a sequence of end views for a layer-by-layer 3D OPA during the layer-by-layer fabrication process, according to at least one embodiment;

FIG. 8 is an end view of the layer-by-layer 3D OPA after the layer-by-layer fabrication process, showing potential issues of uneven thickness and misalignment between layers, according to at least one embodiment;

FIG. 9 is a flowchart illustrating an exemplary method of fabricating a 3D OPA using a simultaneous-lithography process to produce a self-aligned, according to at least one embodiment; and

FIG. 10 shows a 3D edge-firing OPA throughout five different stages during a single lithography fabrication process, according to at least one embodiment.

### DETAILED DESCRIPTION

The system and method described herein enables an optical phased array device having a three-dimensional (3D) edge-firing optical phased array (OPA) to be manufactured or fabricated using a collective lithography step in which multiple waveguide layers are etched simultaneously. According to embodiments, the collective lithography step includes performing a vertical or orthogonal dry etching on a waveguide-cladding stack of alternating waveguide and cladding layers. The collective lithography step results in an etched waveguide-cladding stack with a plurality of waveguides having waveguide paths shaped according to the pattern etched during the collective lithography step. The etched waveguide-cladding stack is then covered with a cladding deposition layer that at least partly envelopes the etched waveguide-cladding stack. According to embodiments, dry reactive ion etching (RIE) is used to etch precise vertical cuts so that the same pattern is maintained for each of the etched layers during the collective lithography step.

The plurality or set of waveguide paths of the 3D edge-firing OPA terminate at a common end or edge at which light is (or other electromagnetic waves are) emitted and, thus, such OPAs are referred to as edge-firing. The set of waveguide paths terminate at the common end or edge (collectively, referred to as “common edge”), and the ends or terminal portions of each waveguide path are spaced apart along a first axis, which is considered to extend in a first dimension. In embodiments, the spacing may be set according to a waveguide pattern and this waveguide pattern may be periodic or aperiodic, which means that the spacing between adjacent elements is uniform (periodic) or non-uniform (aperiodic) throughout. Thus, according to at least some embodiments, each waveguide path of the set of waveguide paths ends at the common edge where electromagnetic radiation (referred to herein simply as “light”) is emitted and leaves the optical phased array—these end or terminal portions of the waveguide paths from which light is emitted are referred to as “firing end portions” and “edge emitters.” The set of waveguide paths receive light from a light source that is coupled to the optical phased array.

According to at least some embodiments, the optical phased array device includes the optical phased array, the light source, a light sensor, and a controller. The light source is coupled to the optical phased array so that light may be transmitted through the set of waveguide paths of the optical phased array, and the light sensor is coupled to the optical phased array so that the light sensor may receive light impinged on the optical phased array. The controller is operatively coupled to the light source so as to control generation and emission of light by the light source and is operatively coupled to the light sensor so as to determine information based on the light received at the light sensor. In embodiments, the controller includes at least one processor and memory accessible by the at least one processor, and the memory stores computer instructions that, when executed by the at least one processor, cause the optical phased array device to operate, including transmitting light from the optical phased array and/or processing information concerning light received at the optical phased array.

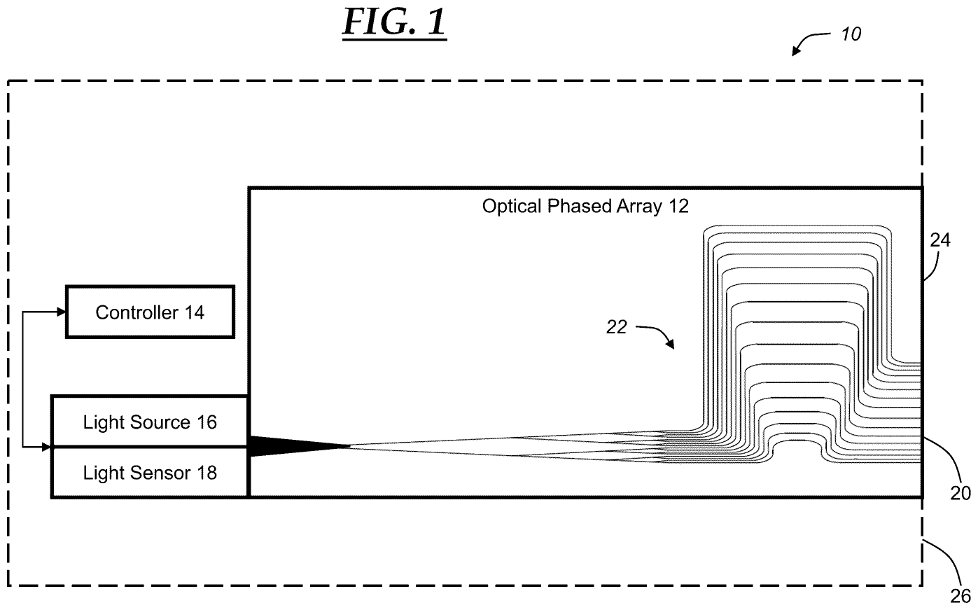

With reference to FIG. 1, there is shown an embodiment of a three-dimensional (3D) optical phased array (OPA) device 10 having an OPA 12, a controller 14, a light source 16, and a light sensor 18. The OPA device 10 may be used for a variety of different applications according to various embodiments, such as, for example, a solid-state lidar device or for a variety of purposes as a part of a photonic integrated circuit. In at least some embodiments, the OPA device 10 may be used for two-dimensional and/or three-dimensional lidar applications, and/or may enable solid state scanning through varying the time delay of emitted light generated from a coherent light produced by the light source 16, for example. It will be appreciated that the depiction of the OPA device 10 in FIG. 1 is diagrammatic and that the optical phased array device may be incorporated into another device or apparatus, and may be a part of a larger system.

The OPA 12 is shown as being operatively coupled to the light source 16 and the light sensor 18, and may be used to transmit light generated or provided by the light source 16 and to receive light impinged at the OPA 12 at the light sensor 18. The OPA 12 is an edge-firing OPA in that it includes a plurality of edge emitters 20 that are disposed at an edge of a planar plate-shaped structure, such as a Silicon-based wafer having a plurality of waveguide layers thereon. The OPA 12 may employ a Silicon-based waveguide structure forming a waveguide array and having a Si₃N₄ pattern layer and a SiO₂ base layer, such as that which is disclosed in U.S. Patent Application Publication No. 2021/0271148 A1, the contents of which are hereby incorporated by reference.

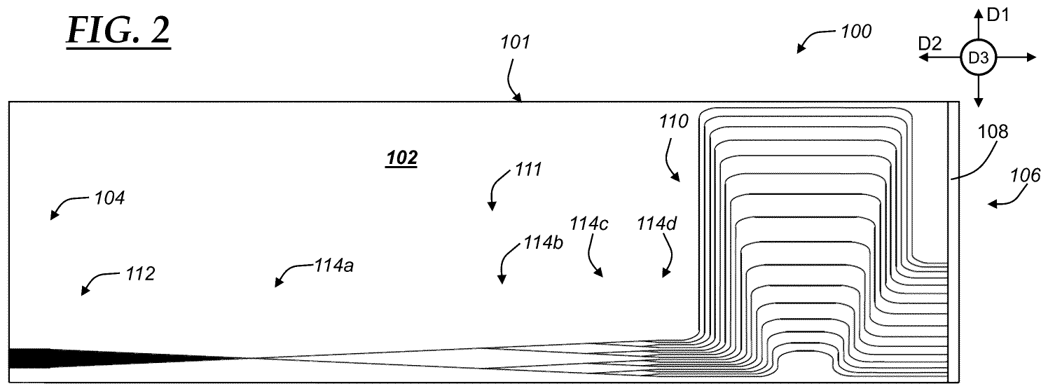

With reference still to FIG. 1, the plurality of edge emitters 20 may be comprised of terminal portions of waveguide paths 22 disposed within a waveguide array of the optical phased array 12. The edge emitters 20 (only a couple labeled in FIG. 1) are disposed at a common edge 24 and are spaced apart from one another in a first dimension D1, which is discussed more below in connection with the optical phased array 100 of FIGS. 2-6. The waveguide paths 22 are shown schematically in FIG. 1 as extending from the light source 16 and light sensor 18 to the edge emitters 20; the depiction of the waveguide paths in FIG. 1 is for purposes of showing which elements are operatively coupled to one another and not for showing actual physical locations, configurations, or shapes of the waveguide paths, which may take a different form, such as that which is shown in FIG. 2 below. The waveguide paths 22 each provide a path through which light is able to travel so that light provided by the light source 16 may be emitted by the edge emitters 20 of the optical phased array 12. And, at least in some embodiments, the waveguide paths 22 each provide a path through which light is able to travel so that light impinged on the edge emitters 20 of the optical phased array 12 is received at the light sensor 18.

In embodiments, the components 12-18 of the optical phased array device 10 may be disposed on a common substrate 26, which may be a printed circuit board, according to one embodiment. In other embodiments, the components 12-18 may be arranged or disposed on different substrates and/or housed in different housings, for example.

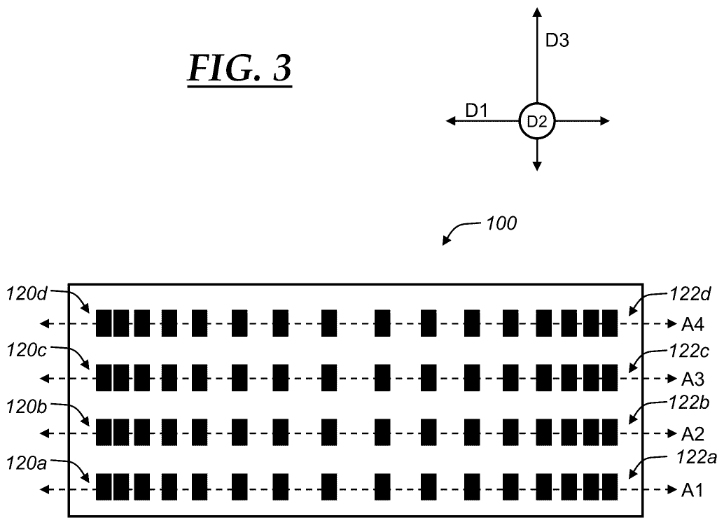

With reference to FIGS. 2-6, there is shown an exemplary three-dimensional (3D) optical phased array (OPA) 100 having four waveguide layers 120a-d (FIG. 3) that may be used as the OPA 12 of the OPA device 10. It will be appreciated that FIGS. 2-5 indicate orientation relative to three dimensions, a first dimension D1, a second dimension D2, and a third dimension D3, which are all orthogonal to one another and that may correspond to X, Y, and Z axes, respectively.

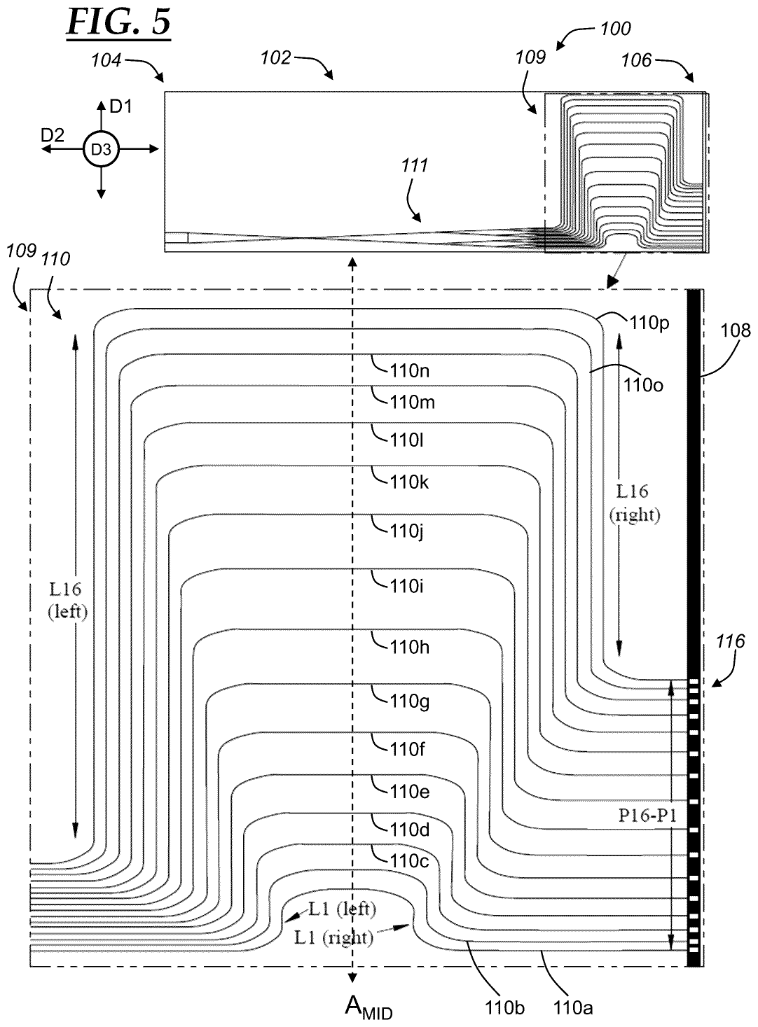

FIG. 3 diagrammatically depicts a side view of the 3D edge-firing OPA 100, along with the four waveguide layers 120a-d, each of which corresponds to a row of edge emitters 122a-d (which correspond to the edge emitters 20 of FIG. 1). Each row of edge emitters 122a-d extends along an axis A1,A2,A3,A4, respectively, extending in the first dimension D1. As will be appreciated, each row of edge emitters 122a-d includes a set of the individual edge emitters 116 (FIG. 5).

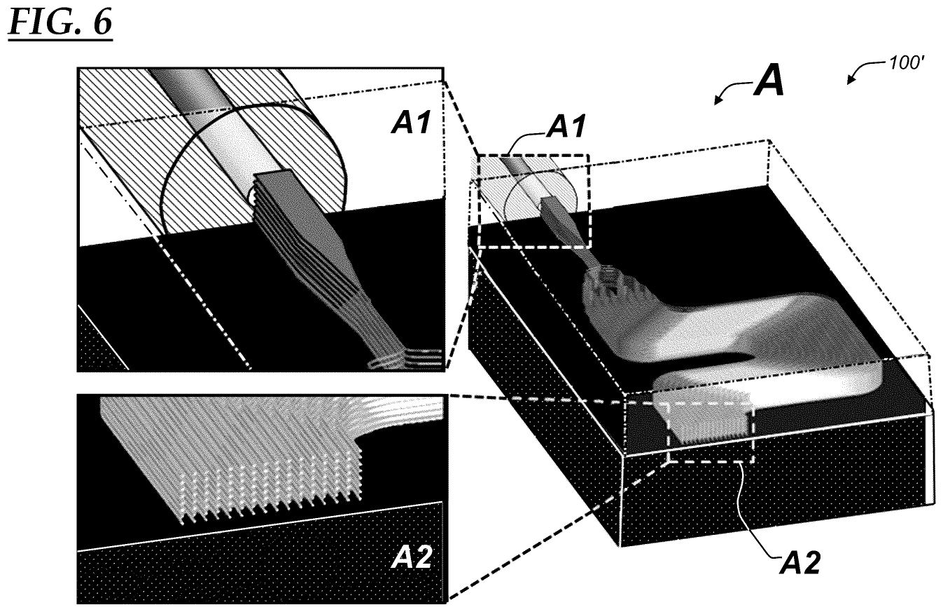

FIG. 6 represents one embodiment of an eight (8) layer 3D edge-firing OPA 100′ that is similar to the four-layer 3D OPA 100 of FIG. 3, but with eight layers. In particular, in FIG. 6 at “A”, there is shown a schematic isometric view of the OPA structure where a single mode fiber (SMF) is used to couple light into the device, and the waveguide width at the coupling region is enlarged to ensure the best mode matching (see zoom-in figure A1); FIG. 6 also depicts a 2D 8×16 emitter array of the 3D OPA 100′ formed at the edge of the device (see zoom-in figure A2), with “B” of FIG. 6 showing a top view layout of the waveguide paths or layers. Of course, in other embodiments, the OPA may have a different number of layers and/or emitters, employing any of a variety of M×N configurations where M is the number of emitter rows (or number of waveguide-cladding layers) and N is the number of emitter columns (or number of waveguide paths within a waveguide-cladding stack). Although the description below discusses the construction and operation of the OPA 100, it will be understood that the description applies also to other OPA embodiments, including the OPA 100′ of FIG. 6.

With specific reference now to FIG. 2, the OPA 100 includes a Silicon-based structure 101, which may be a Silicon-on-insulator (SOI) platform having a plurality of Silicon-based two-dimensional (2D) waveguide arrays 102, and each waveguide array 102 has a collector side 104 and an emitter side 106 disposed on an opposite side of the waveguide array 102 from the collector side 104. The Silicon-based structure 101 may include a Silicon wafer and the plurality of 2D waveguide arrays 102 so as to constitute a 3D optical phased array.

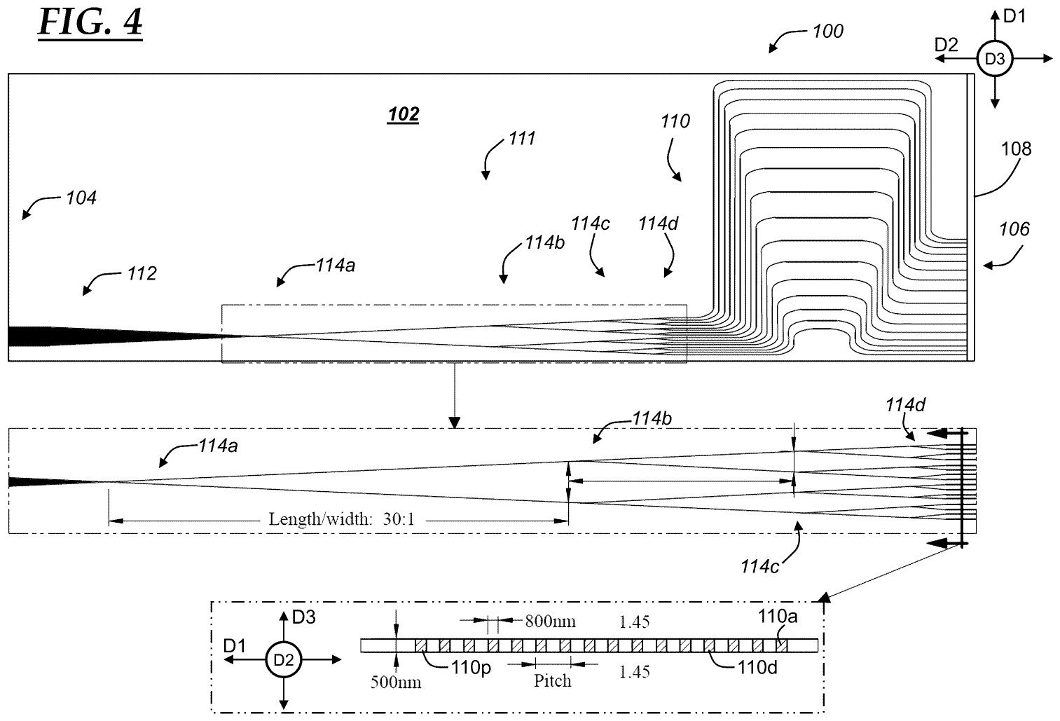

The collector side 104 is configured to be coupled to a light source and light sensor, such as the light source 16 and the light sensor 18 when used as the optical phased array 12 in the optical phased array device 10. The waveguide array 102 includes an edge 108 that extends in the first dimension D1, which is orthogonal to a second dimension D2. The optical phased array 100 includes a plurality or a set of waveguide paths 110 that extend generally in the second dimension D2 from the collector side 104 to the emitter side 106. In particular, the set of waveguide paths 110 start at the collector side 104 and all are formed of a single or common path 112, which then splits or branches in a binary fashion multiple times so that sixteen waveguide paths 110 are generated. The waveguide paths 110 may each be formed as a 1×N multimode interferometer (MMI) 111 where N is the number of waveguide paths, which is sixteen in the depicted embodiment; specifically, in the embodiment depicted in FIGS. 2-4, each waveguide path 110 begins as a part of the common path 112 and then are split four times, at a first binary split or branching portion 114a, a second binary split or branching portion 114b, a third binary split or branching portion 114c, and a fourth binary split or branching portion 114d, so as to yield sixteen unique waveguide paths 110a-p, as shown in FIG. 4. In other embodiments, a different number N of waveguide paths may be used.

With reference now specifically to FIG. 4, there is shown a plan view of the optical phased array 100 with an expanded portion of the tree splitter or MMI 111, which includes the four binary branching portions 114a-d. As shown in the cross-sectional portion of FIG. 3, which is taken at an emitter-side end of the tree splitter 111 where the waveguide paths have been finally split into N separate paths/branches, the height of the waveguide paths 110, taken in the third dimension D3, is 500 nm and the width (taken in the first dimension) of each waveguide path 110a-p is 800 nm. At this portion, each of the waveguide paths 110a-p are separated by a uniform pitch, which may be 2 μm for example; of course, in other embodiments, the pitch may be larger or smaller, such as, for example, 2 μm+/−1.5 μm and/or 2 μm+/−500 nm.

With reference now specifically to FIG. 5, an expanded portion of a phase delay modulator or phase shifter portion 109 is shown in which the waveguide paths 110 each extend in a first direction of the second dimension D2 (from the left to right side of FIG. 4) from the tree splitter 111, then extend in a first direction of the first dimension D1 for a length (referred to as a “first leg length”) (such as is indicated at L1 (left) for waveguide path 110a and L16 (left) for waveguide path 110p), then extend in the first direction of the second dimension D2, then in a second direction of the first dimension D1 that is opposite the first direction of the first dimension D1 for a length (referred to as a “second leg length”) (such as is indicated at L1 (right) for waveguide path 110a and L16 (right) for waveguide path 110p), and finally in the first direction of the second dimension D2 at which the waveguide paths 110a-p each end at a respective one of the emitters 116; this configuration is referred to as an omega (Ω) shaped phase delay configuration. According to one embodiment, the first leg length L1 (left) of the first waveguide path 110a is 5 μm and the second leg length L1 (right) of the first waveguide path 110a is 5 μm. The right-angle or 90 degree turns between the first and second dimensions, as shown in the expanded portion of FIG. 5, may each be rounded in a circular manner with a predetermined radius of curvature, such as, for example, 8 μm; in other embodiments, a smaller or larger radius of curvature may be used, such as, for example, 8 μm+/−4 μm and, preferably in some embodiments, 8 μm+/−1 μm.

As shown in FIG. 5, an axis A_{MID} in the first dimension extends through a middle portion of the phase delay modulator or phase shifter portion 109. In at least one embodiment, spacing along this axis A_{MID} is aperiodic such that spacing, in the first dimension, between adjacent waveguide paths is not uniform; this is different from the uniform spacing that is present at the beginning of the phase delay modulator or phase shifter portion 109, which is shown best in cross-section in FIG. 4. In other embodiments, uniform spacing may be used along the axis A_{MID}.

Within the phase delay modulator portion 109, each waveguide path 110a-p has an omega-shaped delay configuration, such as that which is shown in FIG. 5 and described above. In some embodiments, one or more of the waveguide paths 110a-p does not have an omega-shaped delay configuration, such as the first waveguide path 110a, which may simply be a straight path extending in the second dimension D2 from the tree splitter 111 to the a first one of the emitters 116; in such embodiments, each of the other waveguide paths 110a-p may have an omega-shaped delay configuration. Each of the waveguide paths 110a-p ends or terminates at the edge 108 at a firing portion at which light is emitted and this portion may be referred to as an edge emitter 116.

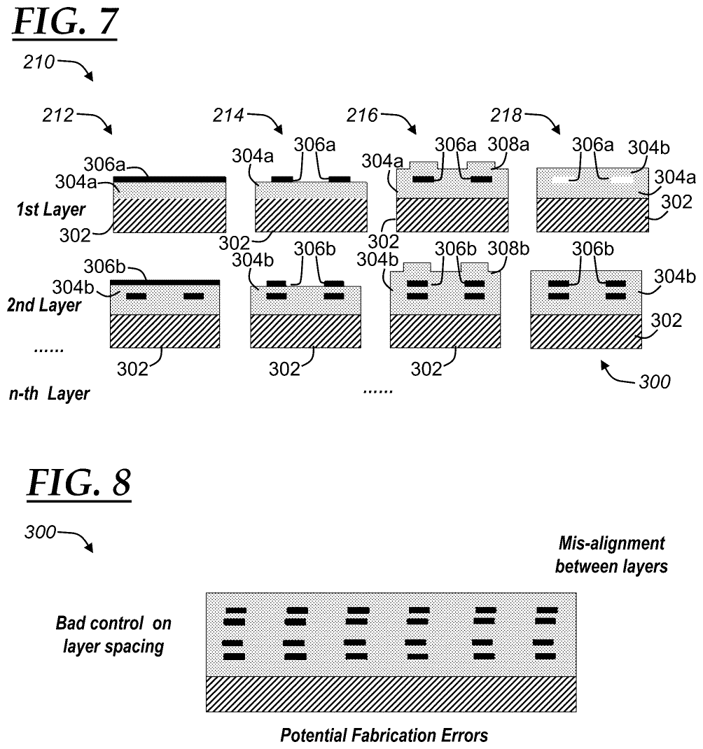

With reference to FIGS. 7-8, there is shown a layer-by-layer fabrication process for fabricating a layer-by-layer 3D OPA 300; in particular, FIG. 7 depicts a sequence of end views for the layer-by-layer 3D OPA during the layer-by-layer fabrication process, and FIG. 8 depicts the layer-by-layer 3D OPA from an end view after the layer-by-layer fabrication process. The layer-by-layer fabrication involves producing individual waveguide layers one at a time by iteratively performing a complimentary metal-oxide semiconductor (CMOS) fabrication process that uses chemical mechanical planarization (CMP). Although possibly suitable for some OPA uses, as discussed below, this layer-by-layer approach causes uneven thickness of layers and/or misalignment between the layers, for example, where the waveguide paths are not accurately coextensive within the first dimension D1 and the second dimension D2.

Generally, the layer-by-layer fabrication process progresses in a layer-by-layer manner, which means that layers of the 3D OPA to be fabricated are deposited one layer at a time such that the layer-by-layer fabrication process includes a separate etching step for each waveguide layer such that the waveguide layers are not etched simultaneously. Indeed, the layer-by-layer fabrication includes generating a waveguide-cladding layer that includes a waveguide layer and a cladding layer; this step is referred to as a waveguide-cladding layer generation step. The waveguide-cladding layer generation step or operation 210 includes: waveguide layer deposition 212, patterning 214, cladding layer deposition 216, and surface polishing 218. More particularly, the waveguide layer deposition 212 is performed in order to deposit waveguide material onto a (first) base cladding layer 304a, which rests upon a base substrate 302; this results in generation of a (first) waveguide layer 306a. The first waveguide layer 306a is then patterned and a cladding layer 308a is deposited onto the patterned waveguide layer 306a, as shown at 216. Then, at 218, CMP is used to planarize or polish the top surface and this cladding layer 304b is used as the next base layer 304b for the next waveguide-cladding layer.

FIG. 7 shows that, in this layer-by-layer process, a whole layering-patterning-cladding-polishing cycle is needed for every layer of the waveguides, and this is consistent with the back-end process in the electronic integrated circuit (IC) industry, which fabricates the interconnection metal layers. In electronic integrated circuits (EICs), it may not be necessary to have precise control over the layer spacing and the alignment between layers; however, in photonic integrated circuits (PICs), especially in the OPA devices, these two issues can negatively impact the phase profile at the emitting surface and cause a distorted farfield pattern.

FIG. 8 illustrates an example of a layer-by-layer or self-aligned OPA that can result from the fabrication process of FIG. 7. As shown therein, the process may result in a self-aligned OPA having undesirable emitter spacing in either or both of the D1 and D3 directions. This can be due to the potential fabrication errors noted above, including the depicted variation of layer spacing and the depicted misalignment between layers. In most OPA applications, a good emitting farfield pattern relies on the accurate arrangement of the array. In a Si 3D OPA, the waveguide core size is typically around 300 nm to 500 nm, in such a case, a 10% fabrication error will be around 30 to 50 nm, and it may not be acceptable. In a Si₃N₄ 3D OPA, the fabrication tolerance is slightly relieved, but still in the range of around 100 nm (˜10% feature size), at least in embodiments. In this layer-by-layer CMOS compatible fabrication process, such a low fabrication tolerance is challenging in either the layer spacing control (relying on the thickness control during a CMP process) or the alignment between layers (relying on the calibration between multiple exposures).

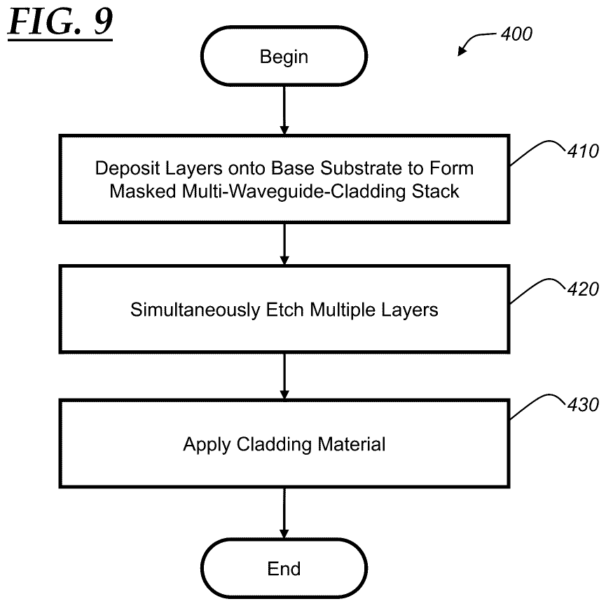

One method to address one or both of these two issues is using a simultaneous-lithography process over multiple waveguide layers to produce a self-aligned OPA rather than the self-aligned OPA of FIGS. 7 and 8. FIG. 9 illustrates an exemplary method 400 of fabricating a three-dimensional (3D) edge-firing optical phased array (OPA), which includes, namely, simultaneously etching multiple layers of a waveguide-cladding stack to form a plurality of waveguide paths, each of which terminates at a common edge. Thus, this exemplary method 400 includes directly patterning multiple waveguide layers together instead of patterning one waveguide layer at a time. This process 400 is useful when multiple waveguide layers are to contain the same pattern (or at least a portion of the whole pattern to be the same); fortunately, this is often the case with OPA devices. In this process, the layer spacing is controlled by CVD, which has very good control over the thickness (the accuracy can be smaller than 10 nm); and because of the simultaneous-lithography process, the waveguide layers are self-aligned. In embodiments, the OPA 100, as well as the OPA 100′ shown in FIG. 6, are fabricated using the method 400.

The method 400 begins with step 410, wherein layers are deposited onto a base substrate to form a multi-waveguide-cladding stack. A multi-waveguide-cladding stack is a waveguide-cladding stack having multiple waveguide-cladding layers. A waveguide-cladding layer refers to a waveguide layer accompanied by a cladding layer. As shown at 510, a waveguide-cladding blank 600 includes a base substrate 602 and a masked multi-waveguide-cladding stack 604 supported by the base substrate 602 and having a multi-waveguide-cladding stack 606 and a mask layer 608. The multi-waveguide-cladding stack 606 includes a plurality of waveguide-cladding layers 610 and are individually referred to by 610-n, where n represents the index of the waveguide-cladding layer with the first waveguide-cladding layer being denoted 610-1, for example, and N represents the number of waveguide-cladding layers. The multi-waveguide-cladding stack 606 includes four waveguide-cladding layers 610-n (N=4). Each of the waveguide-cladding layers 610-n includes a cladding layer 612-n and a waveguide layer 614-n. In embodiments, CVD is used to generate each of the four cladding layers 612-n and the waveguide layers 614-n. Use of CVD to build the multi-waveguide-cladding stack 606 enables accurate layer spacing and enables precise control over layer thickness; in embodiments, this enables creation of layers to be smaller than 10 nm. According to embodiments, the mask layer 608 is generated. The mask layer 608 may be made of a photoresist (PR), such as a standard positive photoresist SPR220, and may be generated using an ACS 200 cluster tool for coating, baking, and developing the PR, with a GCA AutoStep™ used for exposure. The method 400 continues to step 420.

In step 420, simultaneously etching multiple layers of a waveguide-cladding stack to form a plurality of waveguide paths, each of which terminates at a common edge. As shown at 530 (FIG. 9), multiple waveguide-cladding layers are simultaneously etched out of the waveguide-cladding blank 600 so as to form an etched waveguide-cladding structure 620 that is shaped according to the waveguide pattern (used for the etching) when viewed in the plane of the first dimension D1 and the second dimension D2. At least in some embodiments, dry etching is used and, in particular, reactive ion etching (RIE) is used. The simultaneous etching is performed according to an etching profile, which is discussed more below. The method 400 continues to step 430.

In step 430, cladding material is applied to the etched waveguide-cladding structure so as to provide a cladding surrounding the patterned waveguide material. The cladding material is applied using CVD, for example. After applying the cladding material, CMP may be used to planarize the top surface of the OPA by removing excess cladding material. The method 400 then ends.

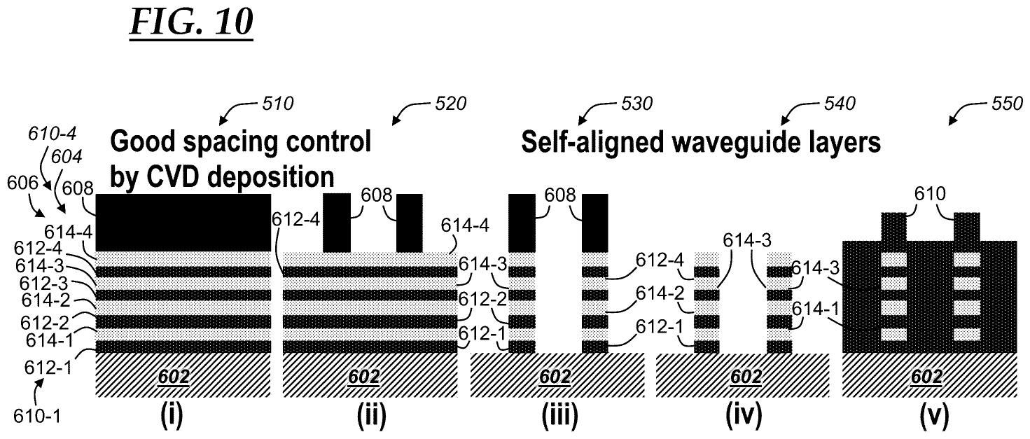

With reference to FIG. 10, there is shown a 3D edge-firing OPA 600 throughout five different stages during a single lithography fabrication process. In embodiments, the method 400, or parts thereof, is/are used to achieve various stages 510-550 shown in FIG. 10. In particular, FIG. 10 illustrates the 3D OPA 600 at five stages: (i) stage 510: masked multi-waveguide-cladding stack generation; (ii) stage 520: mask layer patterning; (iii) stage 530: simultaneous etching of the multi-waveguide-cladding stack; (iv) stage 540: mask removal; and (v) stage 550: cladding deposition.

At the masked multi-waveguide-cladding stack generation stage 510, a masked multi-waveguide-cladding stack 604 is generated. This is carried out as discussed above with respect to step 410 where layers are deposited onto a base substrate to form the multi-waveguide-cladding stack 604. According to embodiments when dry etching, such as RIE, is used, the mask layer is consumed during etching and accordingly, when applied to single-mode applications, the number of waveguide layers that are able to be etched simultaneously depends on the thickness of the mask layer, which depends on the thickness of the photoresist (PR). The thickness of the PR layer is limited by the feature size of the device, and the feature size of the device is the waveguide width, which is limited by the single-mode condition, at least according to embodiments. In the exemplary OPA device 600, Si₃N₄ is selected as the waveguide material due to its better performance in passive devices than Si, and SiO₂ is selected as the cladding material. According to the simulation results, it was discovered that 1100 nanometers (nm) is the largest width that still allows the Si₃N₄ waveguide to be in single-mode. Then, based on this, the thickest PR that can constantly offer 1100 nm resolution is determined, such as is described below, for example.

In embodiments, the PR used for the PR layer is a standard positive photoresist SPR220. An ACS 200 cluster tool may be used for the coating, baking, and developing of the PR, and a GCA AutoStep™ may be used for exposure. Also, the spin rate in the coating step may be tuned to achieve different PR thicknesses, and the exposure matrix method is utilized to determine an exposure time and offset. According to the experiment result, it was found that the thickest PR that is able to offer 1100 nm resolution is approximately 4 μm. An end of an input taper and the first (binary split or) Y-splitter of the device at 4 μm PR was imaged and this imaging was focused when a clear boundary of the larger triangles visible; at this focusing, the narrow waveguides are also in focus, which indicates that the small features and large feature are at the same thickness after PR developing. Also, the same part at 5 μm PR was imaged, where the larger triangular parts can be developed well, but the narrow waveguide lines are not in focus; this means that when the large features are sufficiently developed, the small features are already over-developed. This is a result of the too-thick PR. Therefore, it has been determined that the thickest PR for the 1.1 μm feature size is approximately 4 μm. Of course, it will be appreciated that this is only one embodiment and that different feature sizes and other parameters may be selected according to requirements of the OPA to be fabricated.

At the mask layer patterning stage 520, which may be formed through emitting ultraviolet (UV) light downward through a photomask toward the photoresist (PR) mask layer 608 so that the UV light disintegrates the PR so as to pattern the mask layer 608.

At simultaneous etching stage 530, a self-aligned multi-waveguide-cladding stack 604 is generated as a result of simultaneously etching through multiple layers of the multi-waveguide-cladding stack 604 to generate vertically aligned waveguide paths and terminal portions or emitters. The etchant used for the simultaneous etching may be CF₄, C₄F₈, and/or H₂. In the illustrated embodiment, a soft (or not a hard mask, as in a-Si hard mask) mask etching is performed in the illustrated embodiment of FIG. 10. According to embodiments, a mixture of CF₄, C₄F₈, and H₂ is used as the etchant to achieve different selectivity and directionality. Table 1 below summarizes the etching rate during experimentation using three different etching methods A-C: Method A used only PR as the mask, with etchant composition to achieve the best directionality; Method B used only PR as the mask, with etchant composition to achieve the best selectivity; Method C used a-Si as the hard mask, and this method requires a two-step etching, where the a-Si is firstly etched by PR to generate a patterned a-Si layer, then the Si₃N₄/SiO₂ stack is etched by using the a-Si patterned layer as a mask for simultaneously etching the multi-waveguide-cladding stack. In the experiment, an STS Glass Etcher™ at Lurie Nanofabrication Facility in Ann Arbor, Michigan, was used and the gas mixture included a large amount of helium of 174 sccm and a small portion of etchant gas of a maximum of 40 sccm. A mixture of CF₄, C₄F₈, and H₂ is used as the etchant to achieve different selectivity and directionality; HBr is used to etch the a-Si (in a different tool). Table 1 summarizes the etching rate in the 3 different etching methods, the data are tested on blank wafers.

TABLE 1

| | | | Flow | | | | |
|---|---|---|---|---|---|---|---|
| | | | rate | Etching rate (A/s) | | | |
| Methods | | Etchant | (sccm) | Si₃N₄ | SiO₂ | PR | a-Si |
| A | Best | CF₄ | 40 | 55.7 | 53.1 | 41.7 | — |
| | Directionality | | | | | | |
| B | Best | C₄F₈ | 10 | 45.1 | 32.0 | 8.3 | — |
| | Selectivity | H₂ | 30 | | | | |
| C | Using a-Si | HBr | 100 | — | — | 4.6 | 20.0 |
| | Hard Mask | CF₄ | 20 | 20.6 | 55.7 | — | 8.4 |
| | | C₄F₈ | 20 | | | | |

With fluorocarbon-based etch processes, the reaction depends on a combination of surface passivation of the fluorocarbon and ion bombardment breaking the bonds in the etched material so they can combine with the fluorocarbon, creating a volatile byproduct. At least according to embodiments, the etching itself is highly dependent on the respective rates of these two processes, and the higher the carbon content in the gas mixture used, the faster the passivation rate; this will slow down the etching process since more energy is required to break through the passivation layer, and this effect is stronger on the PR than on SiO₂ and Si₃N₄, so it leads to a higher selectivity. On the other hand, this effect also leads to a more tapered etching profile, since ion bombardment tends to be weaker at the edge of features, and some of the ions will be shadowed by the passivation layer and their trajectories will not be perfectly perpendicular to the wafer surface. In addition, adding H₂ could reduce free fluorine content in plasma, creating a similar effect to higher carbon content.

From the data in Table 1, with the knowledge of the maximum thickness of PR to be 4 μm, the number of waveguide layers that are able to be etched in one lithography or through a simultaneous etching step is calculated. Method A discussed above (see Table 1) has the highest fluorine content, which leads to the best directionality; but on the other hand, the selectivity is lower, so the maximum number of layers that can be etched in one lithography is 4 layers. Method B has the highest carbon content (H₂ further reduces the fluorine content), so this method has the best selectivity, and 14 layers of waveguides are possible to be etched at one time. Method C uses a hard mask, which results in an even larger overall selectivity, so etching 50 layers are possible at one lithography or in one simultaneous etching step. These estimations are simply calculated based on the etching rate from the blank wafer.

The results of the etching profile check were obtained from a test done on the substrate with 3-SiN-layer Si₃N₄/SiO₂ stacks. It can be seen that the etching profile from Method A is very vertical, and this is due to the chamber configuration and gas mixture of the STS Glass Etcher. Because of the relatively small portion of the etchant in the gas mixture, the etching process is extremely ‘diluted’, which inhibits excessive polymerization during the etching; the tool also runs at a very low pressure, which also helps with the etching profile.

From the etching profile of Method B (best selectivity with PR), it can be seen that the gratings are tapered (angled relative to the vertical direction, the third dimension D3). The reason for the taper is the relatively fast growth of the passivation layer, as explained above. Since the taper is already apparent in the 3-SiN-layer substrate, it can be deduced that the tapering effect will be significantly stronger in a 14-SiN-layer substrate, and the top layers will not be able to maintain the dimensions, which may not be acceptable for some 3D OPA devices.

The test etching for Method C was done on a substrate with 3 μm SiO₂, 2 μm a-Si, and 0.97 μm PR. The etching profile after the first step of a-Si etching (etching the a-Si hard mask), it can be seen that the etching of a-Si is fairly vertical, and the etching stopped on the surface of SiO₂ cleanly, this is due to the great selectivity between Si and SiO₂. In this step, about 270 nm PR is consumed. There is shown a picture from eight (8) minutes after the second etching (after the simultaneous etching of the stack) and, at this time, the etching on the SiO₂ is vertical, but the a-Si hard mask already started to degrade because of the faceting effect. This effect usually happens in the etching which is dominated by physical sputtering but not a chemical reaction; in such a process, there is a strong sputter yield dependence on the incidence angle of the incoming ions. In the second step of Method C, the etching rate of a-Si is low, which indicates that this etching is dominated by physical sputtering. At the corner of a feature, which is typically slightly (maybe not even visibly) rounded, a specific angle will develop where the sputter yield is highest, resulting in a degradation of the features. This degradation had not merged into SiO₂ layers at the stage of 8 minutes of SiO/SiN etching, so the SiO₂ features still appear vertical; but, the profile taken after sixteen (16) minutes of the second etching, and the degradation had merged into SiO₂. In the OPA sample, Method C eventually results in that only a few layers of Si₃N₄ waveguide maintain after a long etching, so this method may not be acceptable for some 3D OPA devices.

The etching rate in Table 1 was tested on blank wafers. However, in the small openings, the etching rate is usually slower due to the fact that etchant ions are hard to enter in to such openings. When using Method A, it was calculated that four (4) layers of Si₃N₄ waveguides are possible to be etched in one lithography (one simultaneous etching step). To achieve a full etching on the four (4) layers, small openings may be avoided, at least according to embodiments. The etching profile at small openings is visible through imaging of the OPA, with the images having been taken from a testing wafer containing isolated gratings with different openings, and the grating width is 500 nm. The etching depth at the large openings is approximately 1.2 μm, while at small openings are: (a) 290 nm at 1 μm openings; (b) 1030 nm at 2.5 μm openings; (c) 1040 nm at 4 μm openings; (d) 1200 nm at 5.5 μm openings. A relatively shallow etching is proceeded in the testing to observe the etching differences in small openings. From such images, it can be observed that the etching depth at large openings is approximately 1.2 μm over the whole wafer, while the etching depth is obviously shallower at small openings; it is etched approximately 290 nm at 1 μm openings, 1030 nm at 2.5 μm openings, 1040 nm at 4 μm openings. Eventually, when the opening size reaches 5.5 μm, the etching depth at the center of the openings becomes roughly as same as the depth at large openings.

A completed 4-layer sample was made using a fabrication process that included using a 4 μm PR as the mask layer, Method A for etching, and 6.9 μm as the smallest openings in the device. An image was captured using dedicated backscattering scanning electron microscopy (SEM) imaging. The Y-splitter tree and the delay line region can be distinguished from the image. In the image, four Si₃N₄ end-fire or edge-fire emitters can be distinguished, the image is taken from an angle, which results in the gradient in darkness of the edge emitters from top to bottom. From the image, part of the Y-splitter tree and the 22-shape delay line region can be distinguished. The image is taken from an angle so that the end surface is presented, and the tooth-like shape at every pitch is the result of the plasma enhanced chemical vapor deposition (PECVD) cladding on a high aspect-ratio grating.

The optical performance of the fabricated OPA is tested using a commercial tunable laser and the Fourier optics measurement. The results show that the 3D OPA device can emit a beam with vertical convergence of 17.42°, which indicates that the spacing and calibration between layers are fabricated as design.

The above-described simultaneous etching (or “single lithography”) fabrication process addresses layer spacing issues and layer calibration issues that arise in the normal multi-layer process. In this single lithography process, the layer spacing is controlled by CVD deposition, so the accuracy of the spacing thickness is able to be much better than the control in a CMP process; layer calibration is achieved by self-alignment. In addition, an etching method with a very vertical (aligned in the third dimension D3) etching profile is selected. Therefore, it ensures that the pattern at every waveguide layer is the same. The above-described process was implemented at the LNF and, when implementing such a process somewhere else, the detailed process parameters and the etching possibility may be different. The single lithography fabrication process is more suitable than the conventional method for a multi-waveguide-layer PIC, namely when the PIC is to have the same pattern on every waveguide layer and is sensitive to the fabrication errors in layer spacing and calibration, at least according to embodiments.

It is to be understood that the foregoing description is of one or more embodiments of the invention. The invention is not limited to the particular embodiment(s) disclosed herein, but rather is defined solely by the claims below. Furthermore, the statements contained in the foregoing description relate to the disclosed embodiment(s) and are not to be construed as limitations on the scope of the invention or on the definition of terms used in the claims, except where a term or phrase is expressly defined above. Various other embodiments and various changes and modifications to the disclosed embodiment(s) will become apparent to those skilled in the art.

As used in this specification and claims, the terms “e.g.,” “for example,” “for instance,” “such as,” and “like,” and the verbs “comprising,” “having,” “including,” and their other verb forms, when used in conjunction with a listing of one or more components or other items, are each to be construed as open-ended, meaning that the listing is not to be considered as excluding other, additional components or items. Other terms are to be construed using their broadest reasonable meaning unless they are used in a context that requires a different interpretation. In addition, the term “and/or” is to be construed as an inclusive OR. Therefore, for example, the phrase “A, B, and/or C” is to be interpreted as covering all of the following: “A”; “B”; “C”; “A and B”; “A and C”; “B and C”; and “A, B, and C.”

1. A method of fabricating a three-dimensional (3D) optical phased array (OPA), comprising: simultaneously etching multiple waveguide-cladding layers to form a plurality of waveguide paths, each of which terminates at a common edge.

2. The method of claim 1, wherein the simultaneous etching is carried out using dry etching.

3. The method of claim 2, wherein the simultaneous etching is carried out using reactive ion etching (RIE).

4. The method of claim 1, wherein a mask layer is applied to a top side of a waveguide-cladding stack having the plurality of waveguide-cladding layers prior to the simultaneous etching step.

5. The method of claim 4, wherein the mask layer and the waveguide-cladding stack are simultaneously etched.

6. The method of claim 4, wherein the mask layer is etched prior to the simultaneous etching of the multiple layers of the waveguide-cladding stack.

7. The method of claim 1, wherein two or more of the plurality of waveguide paths include an omega-shaped path portion.

8. The method of claim 1, wherein the method includes obtaining a waveguide-cladding stack having the plurality of waveguide-cladding layers, wherein the waveguide-cladding stack is fabricated using a chemical vapor deposition (CVD) process so as to generate layers of the waveguide-cladding stack that are evenly distributed on a deposition surface thereby resulting in an even thickness of the layers.

9. The method of claim 1, wherein the 3D OPA is an edge-firing OPA.

10. A 3D edge-firing OPA fabricated according to the method of claim 1.

11. An OPA device having:
the 3D edge-firing OPA fabricated according to the method of claim 1; and
a light source coupled to the plurality of waveguides of the 3D edge-firing OPA.

12. A method of fabricating a three-dimensional (3D) edge-firing optical phased array (OPA), comprising: generating a waveguide-cladding stack having a plurality of waveguide layers and a plurality of cladding layers; and simultaneously etching multiple layers of a waveguide-cladding stack to form a plurality of waveguide paths, each of which terminates at a common edge.

13. The method of claim 12, wherein the plurality of waveguide layers and the plurality of cladding layers are interposed so that the waveguide-cladding stack is comprised of alternating waveguide and cladding layers.

14. The method of claim 12, further comprising: disposing a mask layer on a top side of the waveguide-cladding stack, and wherein the simultaneous etching step is performed by etching the waveguide-cladding stack while the mask layer is on the top side of the waveguide-cladding stack.

15. The method of claim 14, wherein the mask layer is etched according to a waveguide pattern prior to performing the simultaneous etching step, and wherein the simultaneous etching step is performed according to the waveguide pattern.

16. An optical phased array having a plurality of self-aligned waveguide layers.

17. The optical phased array of claim 16, wherein the plurality of self-aligned waveguide layers is four or more self-aligned waveguide layers.

18. The optical phased array of claim 16, wherein the plurality of self-aligned waveguide layers is six or more self-aligned waveguide layers.

19. The optical phased array of claim 16, wherein the plurality of self-aligned waveguide layers is eight or more self-aligned waveguide layers.

20. The optical phased array of claim 16, wherein a total number of waveguide layers of the optical phased array is between six and eight, inclusive.
